(19) United States
(12) Patent Application Publication
(10) Pub. No.: US 2024/0321750 A1
(43) Pub. Date: Sep. 26, 2024

(54) SEMICONDUCTOR DEVICE, POWER CONVERSION DEVICE, AND METHOD OF MANUFACTURING SEMICONDUCTOR DEVICE

(71) Applicant: Mitsubishi Electric Corporation, Tokyo (JP)

(72) Inventors: Ryuji UENO, Tokyo (JP); Mikihito SUZUKI, Tokyo (JP); Yuki MAEKAWA, Tokyo (JP); Keisuke MIYOSHI, Tokyo (JP)

(73) Assignee: Mitsubishi Electric Corporation, Tokyo (JP)

(21) Appl. No.: 18/413,761

(22) Filed: Jan. 16, 2024

(30) Foreign Application Priority Data
Mar. 22, 2023 (JP) 2023-045097

(51) Int. Cl. H01L 23/532; H01L 21/768

(52) U.S. Cl. CPC H01L 23/53242; H01L 21/76879; H01L 23/53214

(57) ABSTRACT

An object is to provide a semiconductor device in which an appearance unevenness is reduced in a metal layer on an electrode. A semiconductor device includes a semiconductor substrate, a front surface electrode, a first metal layer, and a second metal layer. The front surface electrode contains Al. The front surface electrode is provided to a front surface of the semiconductor substrate. The first metal layer contains Ni. The first metal layer is provided on the front surface electrode. The second metal layer contains Ni. The second metal layer is provided on the first metal layer. A surface roughness of the first metal layer is larger than that of the second metal layer.

### BACKGROUND OF THE INVENTION

### Field of the Invention

The present disclosure relates to a semiconductor device, a power conversion device, and a method of manufacturing the semiconductor device.

### Description of the Background Art

An electrode of a semiconductor device is bonded to various bonding target object such as a metal wire, a circuit pattern, and a metal plate, for example, depending on a specification of the semiconductor device. An Ni/Au layer, for example, excellent in solder bonding is used to achieve excellent bonding state between the electrode and the bonding target object. An Ni layer is eaten by a solder in the solder bonding and reduced, thus an Ni-containing metal layer having a large thickness needs to be formed on the electrode of the semiconductor device. Such an Ni-containing metal layer having the large thickness is generally formed by a plating method. International Publication No. 2019/111556 discloses an electrolytic plating method for forming an Ni layer in an electrical storage device, although a technical field thereof is different from a semiconductor device.

### SUMMARY

An appearance unevenness may occur in a surface state of an Ni-containing metal layer having a large thickness to which International Publication No. 2019/111556 is applied in some cases. There is a possibility that in a process of forming an electrode of a semiconductor device, a yield in subsequent processes is deteriorated when the apparatus unevenness occurs in the electrode having the large thickness.

An object of the present disclosure is to provide a semiconductor device in which an appearance unevenness is reduced in an Ni-containing metal layer on an electrode.

A semiconductor device according to the present disclosure includes a semiconductor substrate, a front surface electrode, a first metal layer, and a second metal layer. The front surface electrode contains Al. The front surface electrode is provided to a front surface of the semiconductor substrate. The first metal layer contains Ni. The first metal layer is provided on the front surface electrode. The second metal layer contains Ni. The second metal layer is provided on the first metal layer. A surface roughness of the first metal layer is larger than that of the second metal layer

Provided is a semiconductor device in which an appearance unevenness is reduced in an Ni-containing metal layer on an electrode.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view illustrating a configuration of a semiconductor device according to an embodiment 1.

FIG. 2 is an enlarged cross-sectional view illustrating a configuration of the semiconductor device.

FIG. 3 is a flow chart illustrating a method of manufacturing the semiconductor device according to the embodiment 1.

FIG. 4 is a cross-sectional view illustrating a configuration of the semiconductor device in a manufacturing process according to the embodiment 1.

FIG. 5 is a cross-sectional view illustrating a configuration of the semiconductor device in a manufacturing process according to the embodiment 1.

FIG. 6 is a cross-sectional view illustrating a configuration of the semiconductor device in a manufacturing process according to the embodiment 1.

FIG. 7 is a cross-sectional view illustrating a configuration of the semiconductor device in a manufacturing process according to the embodiment 1.

FIG. 8 is a diagram illustrating a detailed process recipe in a method of manufacturing the semiconductor device.

FIG. 9 is a cross-sectional view illustrating a configuration of a semiconductor device according to an embodiment 2.

FIG. 10 is an enlarged cross-sectional view illustrating a configuration of the semiconductor device.

FIG. 11 is a flow chart illustrating a method of manufacturing the semiconductor device according to the embodiment 2.

FIG. 12 is a cross-sectional view illustrating a configuration of the semiconductor device in the manufacturing process according to the embodiment 2.

FIG. 13 is a cross-sectional view illustrating a configuration of the semiconductor device in the manufacturing process according to the embodiment 2.

FIG. 14 is a cross-sectional view illustrating a configuration of the semiconductor device in the manufacturing process according to the embodiment 2.

FIG. 15 is a cross-sectional view illustrating a configuration of the semiconductor device in the manufacturing process according to the embodiment 2.

FIG. 16 is a diagram illustrating a detailed process recipe in a method of manufacturing the semiconductor device.

FIG. 17 is a functional block diagram illustrating a configuration of a power conversion system according to an embodiment 3.

### DESCRIPTION OF THE PREFERRED EMBODIMENTS

### Embodiment 1

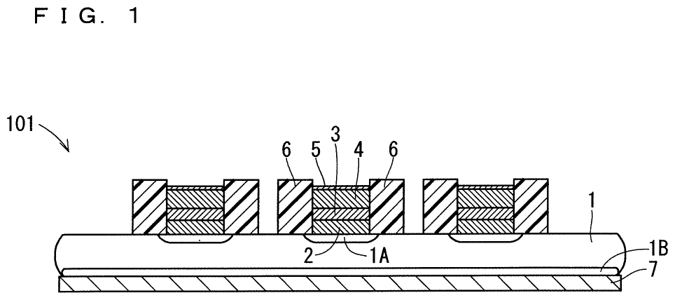

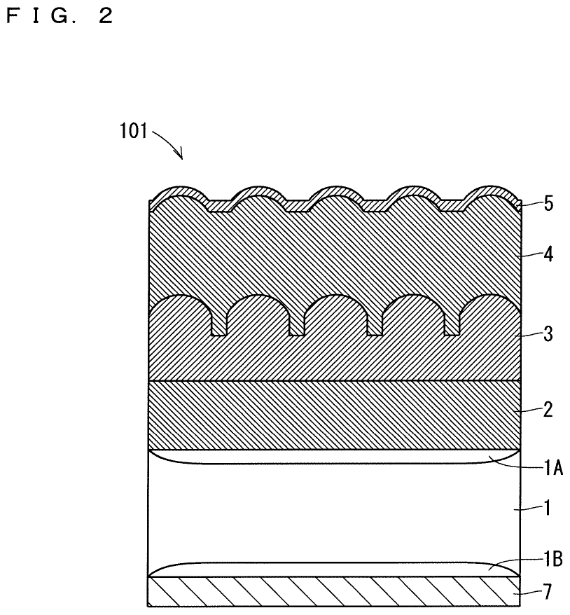

FIG. 1 is a cross-sectional view illustrating a configuration of the semiconductor device 101 according to an embodiment 1. FIG. 2 is an enlarged cross-sectional view illustrating a configuration of the semiconductor device 101. The semiconductor device 101 includes a semiconductor substrate 1, a front surface electrode 2, a first metal layer 3, a second metal layer 4, a front surface-side noble metal film 5, a protection film 6, and a back surface electrode 7.

The semiconductor substrate 1 is also referred to as the semiconductor wafer. A semiconductor element (not shown) is formed in the semiconductor substrate 1. The semiconductor element includes a front surface element region 1A and a back surface diffusion region 1B. The front surface element region 1A is formed in a surface layer on a front surface side of the semiconductor substrate 1. The back surface diffusion region 1B is formed in a surface layer on a back surface side of the semiconductor substrate 1. The semiconductor element according to the embodiment 1 is a vertical semiconductor element in which current flows between the front surface element region 1A and the back surface diffusion region 1B.

The semiconductor element is formed of a semiconductor such as Si or a so-called wide bandgap semiconductor such as SiC, GaN, Ga₂O₃, or diamond, for example. The semiconductor element is an element included in a power semiconductor element or a control integrated circuit (IC) for controlling the power semiconductor element, for example. The semiconductor element is an insulated gate bipolar transistor (IGBT), a metal oxide semiconductor field effect transistor (MOSFET), or a Schottky barrier diode, for example. The semiconductor element may be a reverse-conducting IGBT (RC-IGBT) in which an IGBT and a reflux diode are formed in one semiconductor substrate 1.

The front surface electrode 2 is provided on the front surface element region 1A, that is to say, a front surface of the semiconductor substrate 1. The front surface electrode 2 contains Al. The front surface electrode 2 is an Al alloy layer containing AlSi, AlCu, or AlSiCu, for example.

The first metal layer 3 is provided on the front surface electrode 2. The first metal layer 3 contains Ni. The first metal layer 3 is formed by a non-electrolytic plating method, for example. The first metal layer 3 according to the embodiment 1 is a non-electrolytic Ni plating layer.

The second metal layer 4 is provided on the first metal layer 3. The second metal layer 4 contains Ni. The second metal layer 4 is formed by a non-electrolytic plating method, for example. The second metal layer 4 according to the embodiment 1 is a non-electrolytic Ni plating layer.

A surface roughness of the first metal layer 3 is larger than that of the second metal layer 4. The surface roughness is measured by a contact or non-contact measurement apparatus, for example. The surface roughness is measured by an atomic force microscope (AFM), a scanning electron microscope (SEM), or an optical interferometer, for example.

The front surface-side noble metal film 5 is provided on the second metal layer 4. The front surface-side noble metal film 5 includes more nobler metal than the second metal layer 4. The front surface-side noble metal film 5 according to the embodiment 1 contains Au. A thickness of the front surface-side noble metal film 5 is smaller than that of the first metal layer 3 and the second metal layer 4, for example. The front surface-side noble metal film 5 prevents oxidation of the second metal layer 4. As described hereinafter, the front surface-side noble metal film 5 is formed by a non-electrolytic plating method, for example. The front surface-side noble metal film 5 according to the embodiment 1 is a non-electrolytic Au plating film.

The protection film 6 is provided to cover an edge of the front surface electrode 2. The protection film 6 is formed of polyimide, for example.

The back surface electrode 7 is provided on the back surface diffusion region 1B, that is to say, a back surface of the semiconductor substrate 1. The back surface electrode 7 according to embodiment 1 has a structure in which an Al alloy layer, a Ti layer, an Ni layer, and an Au layer are stacked in this order. The Al alloy layer contains AlSi, AlCu, or AlSiCu, for example. The Al alloy layer improves bonding properties between the back surface electrode 7 and the semiconductor substrate 1. The Ti layer functions as a barrier metal. The Ni layer and the Au layer are provided to obtain favorable bonding properties with a wiring (not shown) connected to the semiconductor device 101 or a bonding material (not shown) for a wiring. The bonding material is solder, for example.

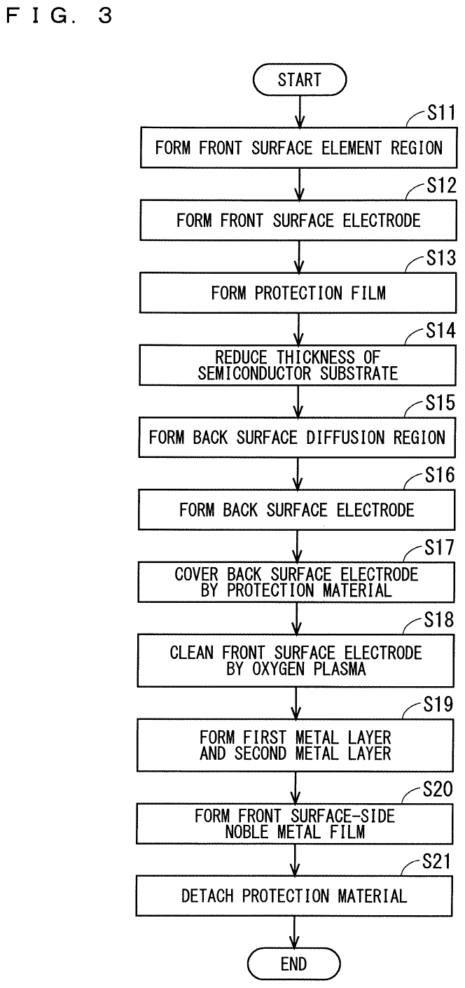

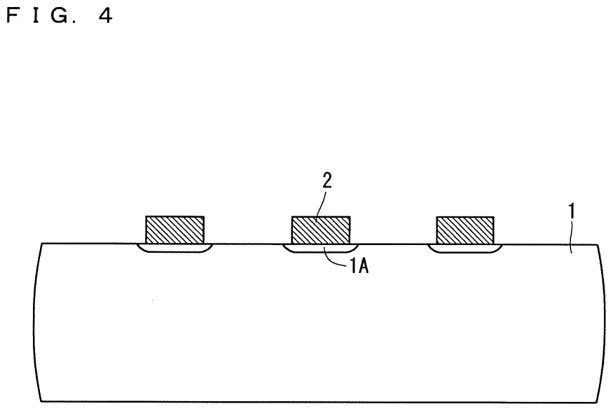

FIG. 3 is a flow chart illustrating a method of manufacturing the semiconductor device 101 according to the embodiment 1. FIG. 4 to FIG. 7 are cross-sectional views each illustrating a configuration of the semiconductor device 101 in a manufacturing process according to the embodiment 1.

In Step S11, the front surface element region 1A is formed. As illustrated in FIG. 4, the front surface element region 1A is formed in the surface layer on the front surface side of the semiconductor substrate 1.

In Step S12, the front surface electrode 2 is formed on the front surface of the semiconductor substrate 1. As illustrated in FIG. 4, the front surface electrode 2 is formed in a predetermined region on the front surface element region 1A. The front surface electrode 2 is formed by a sputtering method. The front surface electrode 2 according to the embodiment 1 is the Al alloy layer.

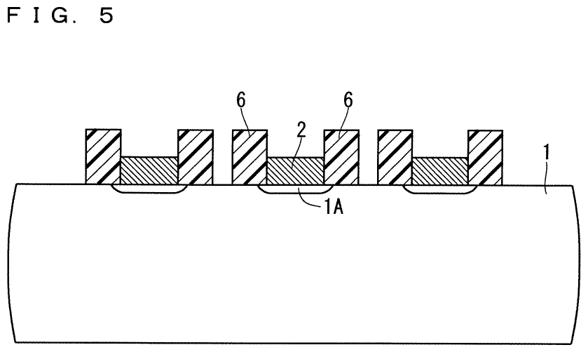

In Step S13, the protection film 6 is formed. As illustrated in FIG. 5, the protection film 6 is formed to cover the edge of the front surface electrode 2. The protection film 6 is formed of polyimide.

In Step S14, the back surface of the semiconductor substrate 1 is mechanically polished to reduce a thickness of the semiconductor substrate 1. A defect layer occurs in the back surface of the semiconductor substrate 1 by the mechanical polishing. Wet etching is performed on a semiconductor layer having a thickness of 5 to 20 μm in the back surface of the semiconductor substrate 1 to remove the defect layer. The semiconductor substrate 1 is thinned to have a predetermined thickness.

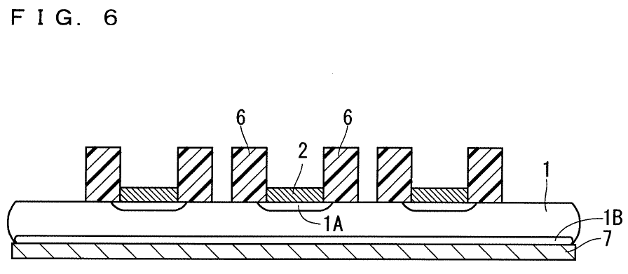

In Step S15, the back surface diffusion region 1B is formed. As illustrated in FIG. 6, the back surface diffusion region 1B is formed in the surface layer on the back surface side of the semiconductor substrate 1.

In Step S16, the back surface electrode 7 is formed. As illustrated in FIG. 6, the back surface electrode 7 is formed on the back surface diffusion region 1B, that is to say, the back surface of the semiconductor substrate 1. The back surface electrode 7 is formed by a sputtering method. Herein, the Al alloy layer, the Ti layer, the Ni layer, and the Au layer are formed in this order as the back surface electrode 7.

In Step S17, the back surface electrode 7 is covered by a protection material (not shown). The protection material is a polyethylene terephthalate (PET) film, for example. The first metal layer 3, the second metal layer 4, and the front surface-side noble metal film 5 according to the embodiment 1 are formed by a non-electrolytic plating method as described hereinafter. The protection material protects the back surface electrode 7 from a medical solution such as a plating solution used in the non-electrolytic plating method.

In Step S18, the front surface of the front surface electrode 2 is cleaned by oxygen plasma. A residue of an organic material adhering to the front surface electrode 2 is oxidized and resolved by this oxygen plasma cleaning processing. A strong residue which cannot be removed by preprocessing of the non-electrolytic plating method described hereinafter is also removed. The front surface electrode 2 is wholly cleaned, thus wettability of the front surface electrode 2 and a plating solution is improved, and uniform displacement reaction is promoted. As a result, the first metal layer 3 having favorable adhesiveness with the front surface electrode 2 can be formed.

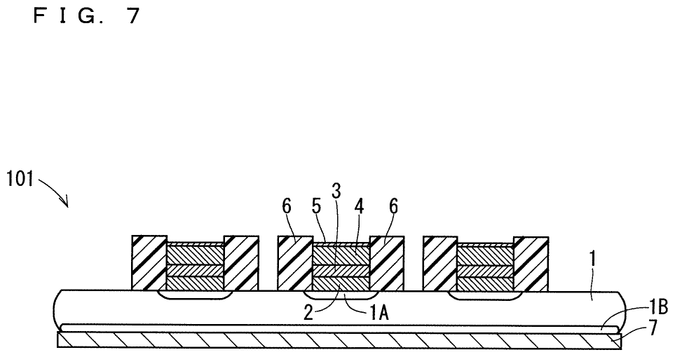

In Step S19, the first metal layer 3 and the second metal layer 4 are formed. As illustrated in FIG. 7, the first metal layer 3 is formed on the front surface electrode 2, and the second metal layer 4 is formed on the first metal layer 3. The first metal layer 3 and the second metal layer 4 are formed by the non-electrolytic plating method. The first metal layer 3 and the second metal layer 4 are non-electrolytic Ni plating layers containing Ni, and are formed by a zincate method. In the zincate method, Al in the surface layer of the front surface electrode 2 is replaced with Zn, and Zn is deposited on the surface layer. Furthermore, a plating layer containing Ni is formed on Zn as a start point. A procedure of the zincate method is described hereinafter.

The semiconductor substrate 1 disposed in a carrier is immersed in an alkaline degreasing solution. Grease and an organic material adhering to the front surface electrode 2 are removed.

Acid cleaning is performed. The acid cleaning removes oxidized material formed on the surface layer of the front surface electrode 2 and roughens the surface of the front surface electrode 2. Accordingly, reactiveness in the zincate processing performed after the acid cleaning is increased, and this causes improvement of adhesiveness between the front surface electrode 2 and the first metal layer 3.

The semiconductor substrate 1 is immersed in an alkaline zincate processing solution. Standard oxidation-reduction potential of Zn is nobler than Al, thus Al in the surface layer of the front surface electrode 2 is replaced with Zn, and Zn is deposited on the surface layer. Subsequently, the semiconductor substrate 1 is immersed in nitric acid. Zn deposited on the front surface electrode 2 is removed by the nitric acid. Subsequently, the semiconductor substrate 1 is again immersed in an alkaline zincate processing solution. Al in the surface layer of the front surface electrode 2 is replaced with Zn, and Zn is deposited on the surface layer. The zincate processing is repeated, thus an accurate Zn film is formed on the surface of the front surface electrode 2. Such an accurate Zn film improves adhesiveness between the Ni plating film formed on Zn as a start point and the front surface electrode 2. The number of repetitions of the zincate processing is preferably twice or more, and is preferably three at most in consideration of productivity.

The semiconductor substrate 1 is immersed in an acid non-electrolytic Ni plating solution to form the first metal layer 3. A circulation flow rate of the non-electrolytic Ni plating solution in forming the first metal layer 3 is 50 L/min. Firstly, Zn in the surface layer of the front surface electrode 2 is replaced with Ni, and Ni is deposited on the surface layer. Subsequently, Ni is continuously deposited by a reducing agent included in the non-electrolytic Ni plating solution, and the thickness of the Ni layer increases. The first metal layer 3 is thereby formed. The thickness of the first metal layer 3 is preferably equal to or larger than 0.5 μm and equal to or smaller than 2 μm.

The second metal layer 4 is formed by processing similar to the first metal layer 3, however, an agitation speed of the non-electrolytic Ni plating solution is different from that in forming the first metal layer 3. A circulation flow rate of the non-electrolytic Ni plating solution in forming the second metal layer 4 is 25 L/min. Ni is continuously deposited by a reducing agent included in the non-electrolytic Ni plating solution, and the second metal layer 4 is formed. The thickness of the second metal layer 4 is preferably equal to or larger than 1.5 μm and equal to or smaller than 8 μm.

As described above, the agitation speed of the plating solution in the process of forming the first metal layer 3 is larger than that of the plating solution in the process of forming the second metal layer 4.

A total thickness of the first metal layer 3 and the second metal layer 4 is preferably equal to or larger than 2 μm and equal to or smaller than 10 μm also in consideration of film stress applied to the semiconductor substrate 1. The semiconductor substrate 1 is washed with water after forming the first metal layer 3 and the second metal layer 4.

In Step S20, the front surface-side noble metal film 5 is formed. As illustrated in FIG. 7, the front surface-side noble metal film 5 is formed on the second metal layer 4. The front surface-side noble metal film 5 is formed by the non-electrolytic plating method. The front surface-side noble metal film 5 is a non-electrolytic Au plating film containing Au.

In Step S20, the semiconductor substrate 1 is immersed in the non-electrolytic Au plating solution. Accordingly, Au is continuously deposited on the second metal layer 4, and the front surface-side noble metal film 5 is formed. A thickness of the front surface-side noble metal film 5 is equal to or larger than 20 nm and equal to or smaller than 100 nm. The semiconductor substrate 1 is washed with water after forming the front surface-side noble metal film 5.

In Step S21, the protection material covering the back surface electrode 7 is detached. Steps S11 to S21 described above are the method of manufacturing the semiconductor device 101 according to the embodiment 1.

In this manufacturing method, the agitation speed of the plating solution in the process of forming the first metal layer 3 is larger than that of the plating solution in the process of forming the second metal layer 4 as described above. The first metal layer 3 having the larger surface roughness than the second metal layer 4 is formed by such processing.

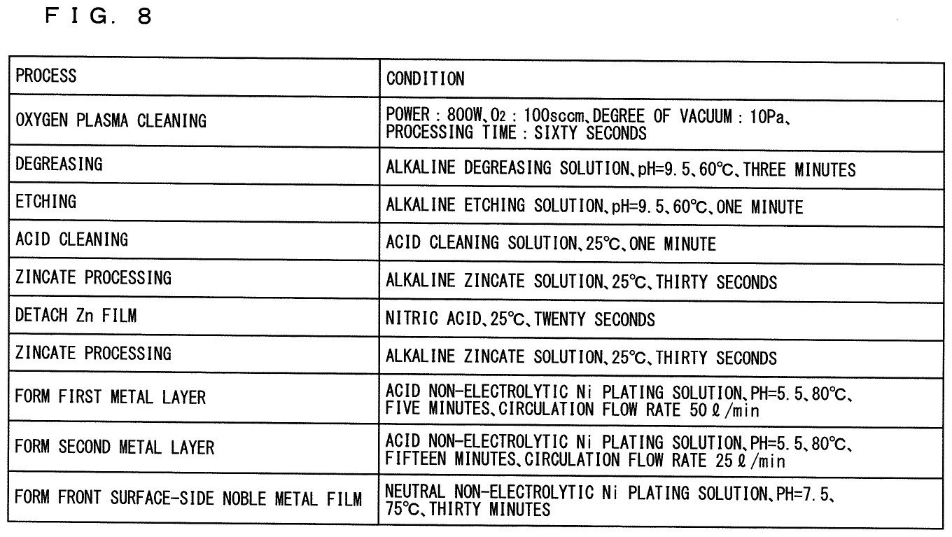

FIG. 8 is a diagram illustrating a detailed process recipe in the method of manufacturing the semiconductor device 101. As a result of manufacturing the semiconductor device 101 with such a process recipe, the surface roughness of the first metal layer 3 is 86.2 nm, and the surface roughness of the second metal layer 4 is 53.2 nm. It is confirmed that an appearance unevenness is reduced in an appearance inspection from above the front surface-side noble metal film 5.

To sum up the above, the semiconductor device 101 according to the embodiment 1 includes the semiconductor substrate 1, the front surface electrode 2, the first metal layer 3, and the second metal layer 4. The front surface electrode 2 contains Al. The front surface electrode 2 is provided to the front surface of the semiconductor substrate 1. The first metal layer 3 contains Ni. The first metal layer 3 is provided on the front surface electrode 2. The second metal layer 4 contains Ni. The second metal layer 4 is provided on the first metal layer 3. The surface roughness of the first metal layer 3 is larger than that of the second metal layer 4.

The appearance unevenness of the second metal layer 4 on the front surface electrode 2 is reduced in such a semiconductor device 101. The reason for this state is that influence of orientation or influence of a grain size of the front surface electrode 2 as a base is reduced, for example. A frequency of visibility defect and an inspection error caused thereby is reduced in an appearance inspection process after the process of the plating processing. Thus, reduction in yield due to delay of work period and a false defect is prevented.

The agitation speed of the plating solution in the process of forming the first metal layer 3 is larger than that of the plating solution in the process of forming the second metal layer 4. Accordingly, occurrence of unevenness of the surface of the second metal layer 4 can be suppressed compared with the first metal layer 3. A difference between the circulation flow rate of the plating solution in forming the first metal layer 3 and the circulation flow rate of the plating solution in forming the second metal layer 4 is preferably larger than at least equal rate. Particularly, when the difference of the circulation flow rate is twice or more, the appearance unevenness is significantly improved. The difference of the agitation speed of the plating solution may be controlled not only by the circulation flow rate of the plating solution but also by a rocking speed of a carrier housing the semiconductor substrate 1, for example.

The agitation indicates a circulation operation of the plating solution in a plating tank by a pump or a rocking operation of a carrier housing the semiconductor substrate 1. The carrier oscillates in a constant direction in the rocking operation of the carrier, thus it is difficult to control a magnitude of fluctuation of the plating solution. In the meanwhile, the circulation operation by the pump forms a flow in which the plating solution is rotated in one direction in the plating tank. Thus, the plating solution can be easily controlled, and the agitation speed can be easily adjusted. That is to say, the agitation speed can be adjusted more easily by controlling the flow of the plating solution by the circulation operation with the pump than the rocking operation of the carrier.

The front surface-side noble metal film 5 containing Au is provided on the second metal layer 4, thus excellent bonding properties with the bonding target object can be obtained. The bonding target object is a metal wire, a circuit pattern, or a metal plate for flowing current to the semiconductor element from outside.

In the vertical semiconductor device 101 in which current flows between the front surface and the back surface of the semiconductor substrate 1, a metal wire is bonded to the front surface electrode 2 and a circuit substrate is bonded to the back surface electrode 7 via a bonding material. A configuration of also bonding the front surface electrode 2 to a metal plate, for example, via a bonding material is being applied to further reduce cost and improve heat radiation properties. In such a configuration, an Ni/Au layer excellent in bonding properties is necessary as the front surface electrode 2. An Ni layer having a film thickness of 2 μm or larger is necessary to achieve favorable bonding properties. The non-electrolytic plating method is preferable to form the Ni layer having the thickness of 2 μm or larger. According to the non-electrolytic plating method, the Ni layer in which cost is reduced and a patterning is easily performed can be formed.

### Embodiment 2

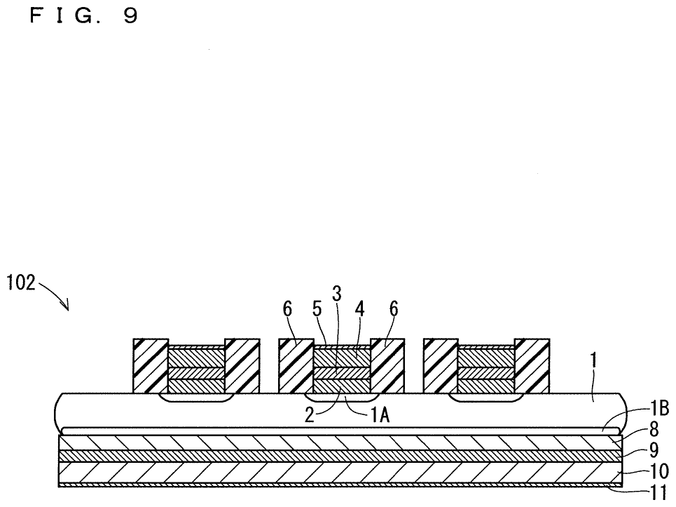

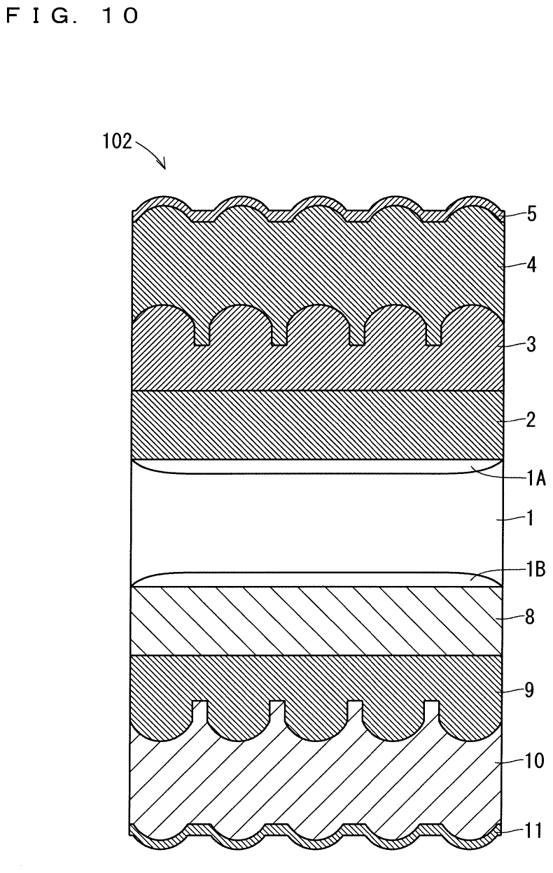

FIG. 9 is a cross-sectional view illustrating a configuration of a semiconductor device 102 according to an embodiment 2. FIG. 10 is an enlarged cross-sectional view illustrating a configuration of the semiconductor device 102. The semiconductor device 102 includes the semiconductor substrate 1, the front surface electrode 2, the first metal layer 3, the second metal layer 4, the front surface-side noble metal film 5, the protection film 6, a back surface electrode 8, a third metal layer 9, a fourth metal layer 10, and a back surface-side noble metal film 11.

Configurations of the semiconductor substrate 1, the front surface electrode 2, the first metal layer 3, the second metal layer 4, the front surface-side noble metal film 5, and the protection film 6 according to the embodiment 2 are the same as those according to the embodiment 1.

The back surface electrode 8 is provided on the back surface diffusion region 1B, that is to say, the back surface of the semiconductor substrate 1. The back surface electrode 8 contains Al. The back surface electrode 8 according to the embodiment 2 is an Al alloy layer including AlSi, AlCu, or AlSiCu, for example.

The third metal layer 9 is provided on the back surface electrode 8. The third metal layer 9 contains Ni. The third metal layer 9 is formed by a non-electrolytic plating method, for example. The third metal layer 9 according to the embodiment 2 is a non-electrolytic Ni plating layer.

The fourth metal layer 10 is provided on the third metal layer 9. The fourth metal layer 10 contains Ni. The fourth metal layer 10 is formed by a non-electrolytic plating method, for example. The fourth metal layer 10 according to the embodiment 2 is a non-electrolytic Ni plating layer.

The surface roughness of the third metal layer 9 is larger than that of the fourth metal layer 10. A composition of the third metal layer 9 is the same as that of the first metal layer 3, and a composition of the fourth metal layer 10 is the same as that of the second metal layer 4.

The back surface-side noble metal film 11 is provided on the fourth metal layer 10. The back surface-side noble metal film 11 includes more nobler metal than the fourth metal layer 10. The back surface-side noble metal film 11 according to the embodiment 2 contains Au. A thickness of the back surface-side noble metal film 11 is smaller than that of the third metal layer 9 and the fourth metal layer 10, for example. The back surface-side noble metal film 11 prevents oxidation of the fourth metal layer 10. As described hereinafter, the back surface-side noble metal film 11 is formed by a non-electrolytic plating method, for example. The back surface-side noble metal film 11 according to the embodiment 2 is a non-electrolytic Au plating film.

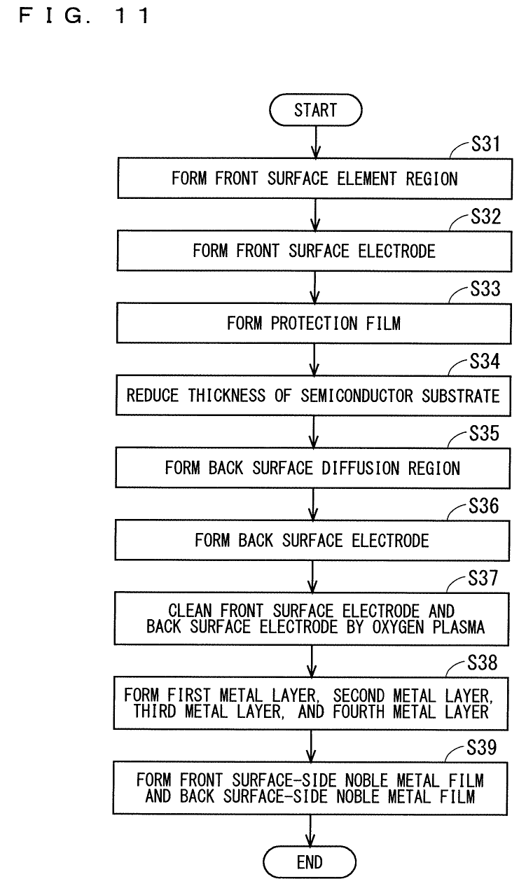

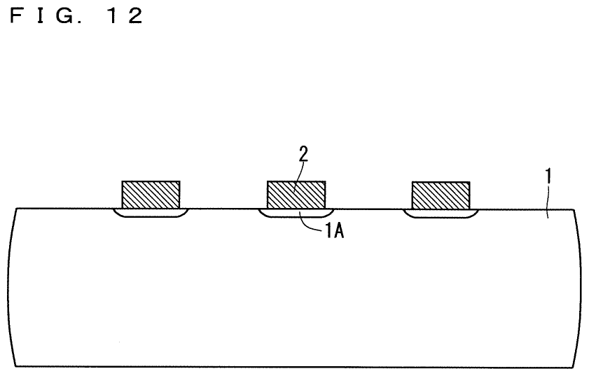

FIG. 11 is a flow chart illustrating a method of manufacturing the semiconductor device 102 according to the embodiment 2. FIG. 12 to FIG. 15 are cross-sectional views each illustrating a configuration of the semiconductor device 102 in a manufacturing process according to the embodiment 2.

In Step S31, the front surface element region 1A is formed. As illustrated in FIG. 12, the front surface element region 1A is formed in the surface layer on the front surface side of the semiconductor substrate 1.

In Step S32, the front surface electrode 2 is formed on the front surface of the semiconductor substrate 1. As illustrated in FIG. 12, the front surface electrode 2 is formed in a predetermined region on the front surface element region 1A. The front surface electrode 2 is formed by a sputtering method. The front surface electrode 2 according to the embodiment 2 is the Al alloy layer.

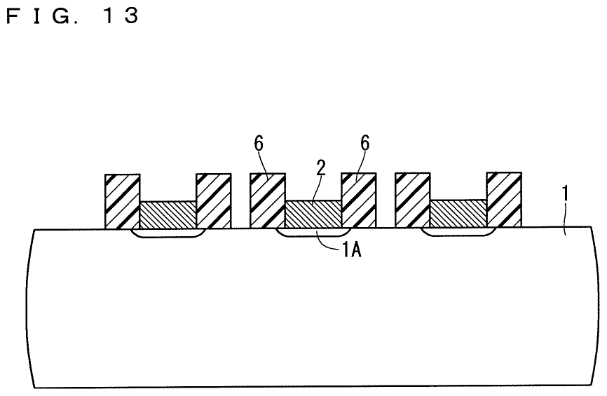

In Step S33, the protection film 6 is formed. As illustrated in FIG. 13, the protection film 6 is formed to cover the edge of the front surface electrode 2. The protection film 6 is formed of polyimide.

In Step S34, the back surface of the semiconductor substrate 1 is mechanically polished to reduce a thickness of the semiconductor substrate 1. A defect layer occurs in the back surface of the semiconductor substrate 1 by the mechanical polishing. Wet etching is performed on a semiconductor layer having a thickness of 5 to 20 μm in the back surface of the semiconductor substrate 1 to remove the defect layer. The semiconductor substrate 1 is thinned to have a predetermined thickness.

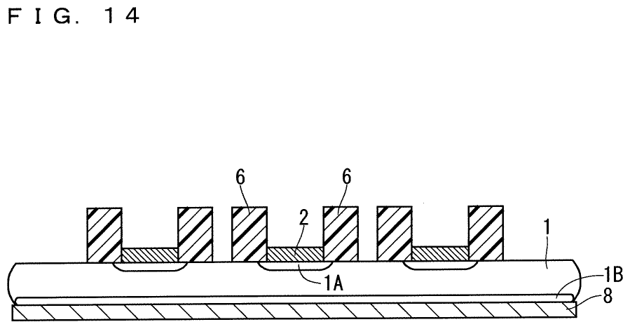

In Step S35, the back surface diffusion region 1B is formed. As illustrated in FIG. 14, the back surface diffusion region 1B is formed in the surface layer on the back surface side of the semiconductor substrate 1.

In Step S36, the back surface electrode 8 is formed. As illustrated in FIG. 14, the back surface electrode 8 is formed on the back surface diffusion region 1B, that is to say, the back surface of the semiconductor substrate 1. The back surface electrode 8 is formed by a sputtering method. The back surface electrode 8 according to the embodiment 2 is an Al alloy layer made of AlSi, AlCu, or AlSiCu, for example.

In Step S37, the front surfaces of the front surface electrode 2 and the back surface electrode 8 are cleaned by oxygen plasma. A residue of an organic material adhering to the front surface electrode 2 and the back surface electrode 8 is oxidized and resolved by this oxygen plasma cleaning processing. A strong residue which cannot be removed by preprocessing of the non-electrolytic plating method described hereinafter is also removed. The front surface electrode 2 and the back surface electrode 8 are wholly cleaned, thus wettability of the front surface electrode 2 and a plating solution and wettability of the back surface electrode 8 and the plating solution are improved, and uniform displacement reaction is promoted. As a result, the first metal layer 3 having favorable adhesiveness with the front surface electrode 2 and the third metal layer 9 having favorable adhesiveness with the back surface electrode 8 can be formed.

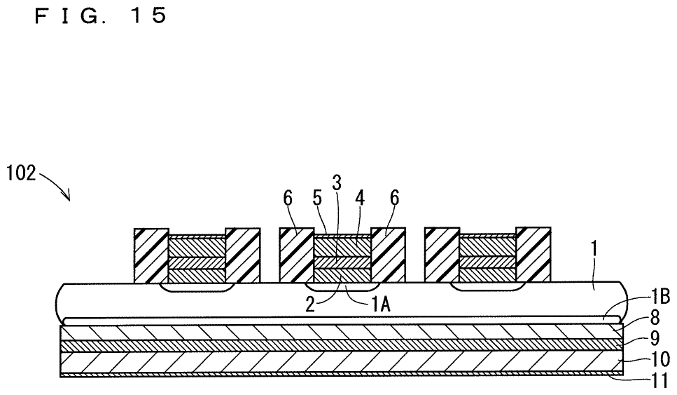

In Step S38, the first metal layer 3, the second metal layer 4, the third metal layer 9, and the fourth metal layer 10 are formed. As illustrated in FIG. 15, the first metal layer 3 is formed on the front surface electrode 2, and the second metal layer 4 is formed on the first metal layer 3. The third metal layer 9 is formed on the back surface electrode 8, and the fourth metal layer 10 is formed on the third metal layer 9. The first metal layer 3, the second metal layer 4, the third metal layer 9, and the fourth metal layer 10 are formed by the non-electrolytic plating method. The first metal layer 3, the second metal layer 4, the third metal layer 9, and the fourth metal layer 10 are non-electrolytic Ni plating layers containing Ni, and are formed by a zincate method. A procedure of the zincate method is described hereinafter.

The semiconductor substrate 1 disposed in a carrier is immersed in an alkaline degreasing solution. Grease and an organic material adhering to the front surface electrode 2 and the back surface electrode 8 are removed.

Acid cleaning is performed. The acid cleaning removes oxidized material formed on the surface layer of the front surface electrode 2 and the back surface electrode 8, and roughens the surfaces of the front surface electrode 2 and the back surface electrode 8. Accordingly, reactiveness in the zincate processing performed after the acid cleaning is increased, and this causes improvement of adhesiveness between the front surface electrode 2 and the first metal layer 3 and adhesiveness between the back surface electrode 8 and the third metal layer 9.

The semiconductor substrate 1 is immersed in an alkaline zincate processing solution. Al in the surface layers of the front surface electrode 2 and the back surface electrode 8 is replaced with Zn, and Zn is deposited on the surface layers. Subsequently, the semiconductor substrate 1 is immersed in nitric acid. Zn deposited on the front surface electrode 2 and the back surface electrode 8 is removed by the nitric acid. Subsequently, the semiconductor substrate 1 is again immersed in an alkaline zincate processing solution. Al in the surface layers of the front surface electrode 2 and the back surface electrode 8 is replaced with Zn, and Zn is deposited on the surface layers. The zincate processing is repeated, thus an accurate Zn film is formed on the surfaces of the front surface electrode 2 and the back surface electrode 8. Such an accurate Zn film improves adhesiveness between the Ni plating film formed on Zn as a start point and the front surface electrode 2 and adhesiveness between the Ni plating film and the back surface electrode 8. The number of repetitions of the zincate processing is preferably twice or more, and is preferably three at most in consideration of productivity.

The semiconductor substrate 1 is immersed in an acid non-electrolytic Ni plating solution to form the first metal layer 3 and the third metal layer 9. A circulation flow rate of the non-electrolytic Ni plating solution in forming the first metal layer 3 and the third metal layer 9 is 50 L/min. Firstly, Zn in the surface layers of the front surface electrode 2 and the back surface electrode 8 is replaced with Ni, and Ni is deposited on the surface layers. Subsequently, Ni is continuously deposited by a reducing agent included in the non-electrolytic Ni plating solution, and the thickness of the Ni layer increases. The first metal layer 3 and the third metal layer 9 are thereby formed. In the embodiment 2, the process of forming the third metal layer 9 and the process of forming the first metal layer 3 are performed at the same time. That is to say, the composition of the third metal layer 9 is the same as that of the first metal layer 3. The thickness of the first metal layer 3 and the third metal layer 9 is preferably equal to or larger than 0.5 μm and equal to or smaller than 2 μm.

Next, the second metal layer 4 and the fourth metal layer 10 are formed. The agitation speed of the non-electrolytic Ni plating solution in forming the second metal layer 4 and the fourth metal layer 10 is different from that in forming the first metal layer 3 and the third metal layer 9. A circulation flow rate of the non-electrolytic Ni plating solution in forming the second metal layer 4 and the fourth metal layer 10 is 25 L/min. Ni is continuously deposited by a reducing agent included in the non-electrolytic Ni plating solution, and the second metal layer 4 and the fourth metal layer 10 are formed. In the embodiment 2, the process of forming the fourth metal layer 10 and the process of forming the second metal layer 4 are performed at the same time. That is to say, the composition of the fourth metal layer 10 is the same as that of the second metal layer 4. The thickness of the second metal layer 4 and the fourth metal layer 10 is preferably equal to or larger than 1.5 μm and equal to or smaller than 8 μm.

As described above, the agitation speed of the plating solution in the process of forming the first metal layer 3 and the third metal layer 9 is larger than that of the plating solution in the process of forming the second metal layer 4 and the fourth metal layer 10.

A total thickness of the first metal layer 3 and the second metal layer 4 is preferably equal to or larger than 2 μm and equal to or smaller than 10 μm also in consideration of film stress applied to the semiconductor substrate 1. In the similar manner, a total thickness of the third metal layer 9 and the fourth metal layer 10 is preferably equal to or larger than 2 μm and equal to or smaller than 10 m. The semiconductor substrate 1 is washed with water after forming the first metal layer 3, the second metal layer 4, the third metal layer 9, and the fourth metal layer 10.

In Step S39, the front surface-side noble metal film 5 and the back surface-side noble metal film 11 are formed. As illustrated in FIG. 15, the front surface-side noble metal film 5 is formed on the second metal layer 4, and the back surface-side noble metal film 11 is formed on the fourth metal layer 10. The front surface-side noble metal film 5 and the back surface-side noble metal film 11 are formed by the non-electrolytic plating method. The front surface-side noble metal film 5 and the back surface-side noble metal film 11 are non-electrolytic Au plating films containing Au. In Step S39, the semiconductor substrate 1 is immersed in the non-electrolytic Au plating solution. Accordingly, Au is continuously deposited on the second metal layer 4 and the fourth metal layer 10, and the front surface-side noble metal film 5 and the back surface-side noble metal film 11 are formed. A thickness of the front surface-side noble metal film 5 and the back surface-side noble metal film 11 is equal to or larger than 20 nm and equal to or smaller than 100 nm. The semiconductor substrate 1 is washed with water after forming the front surface-side noble metal film 5 and the back surface-side noble metal film 11. Steps S31 to S39 described above are the method of manufacturing the semiconductor device 102 according to the embodiment 2.

In this manufacturing method, as described above, the agitation speed of the plating solution in the process of forming the first metal layer 3 and the third metal layer 9 is larger than that of the plating solution in the process of forming the second metal layer 4 and the fourth metal layer 10. The first metal layer 3 having the larger surface roughness than the second metal layer 4 is formed by such processing. In the similar manner, the third metal layer 9 having the larger surface roughness than the fourth metal layer 10 is formed.

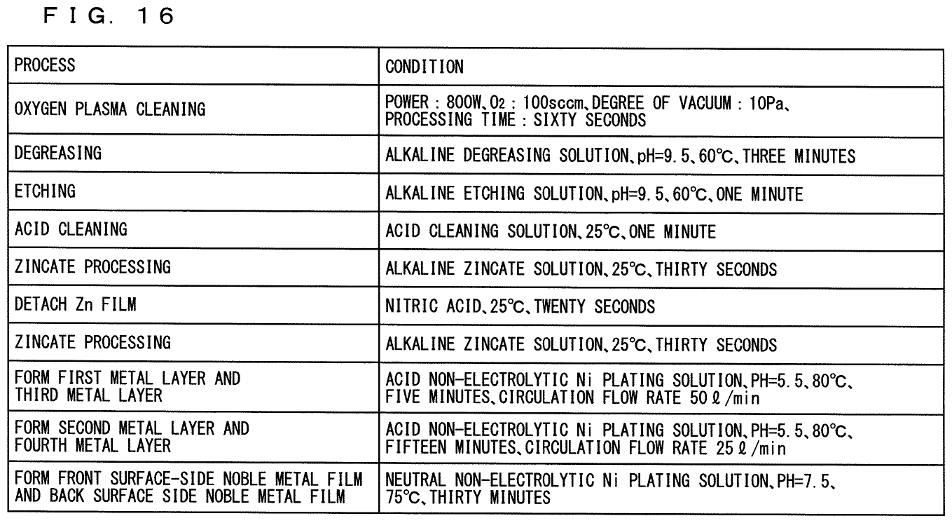

FIG. 16 is a diagram illustrating a detailed process recipe in a method of manufacturing the semiconductor device 102. It is confirmed that an appearance unevenness is reduced in an appearance inspection from above the front surface-side noble metal film 5 and an appearance inspection from above the back surface-side noble metal film 11.

In the embodiment 2, the non-electrolytic Ni plating layer on the front surface side of the semiconductor substrate 1 and the non-electrolytic Ni plating layer on the back surface side thereof are formed at the same time, but may also be formed separately. For example, the third metal layer 9 and the fourth metal layer 10 on the back surface side of the semiconductor substrate 1 may be formed after the first metal layer 3 and the second metal layer 4 on the front surface side thereof are formed. The first metal layer 3 and the second metal layer 4 on the front surface side of the semiconductor substrate 1 may be formed after the third metal layer 9 and the fourth metal layer 10 on the back surface side thereof are formed.

### Embodiment 3

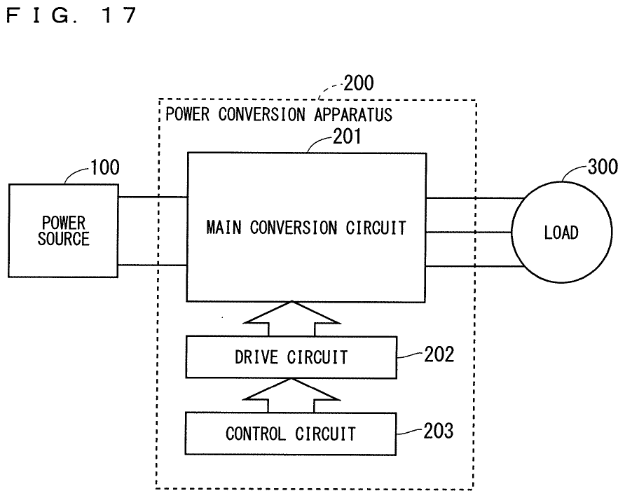

FIG. 17 is a functional block diagram illustrating a configuration of a power conversion system according to the embodiment 3.

The power conversion system includes a power source 100, a power conversion device 200, and a load 300.

The power source 100 is a direct current power source. The power source 100 supplies direct current power to the power conversion device 200. The power source 100 is a direct current system, a solar battery, and a rechargeable battery, for example. The power source 100 may also be made up of a DC/DC converter which converts direct current power outputted from the direct current system into predetermined power. The power source 100 may be a rectification circuit connected to an alternating current system or an AC/DC converter, for example.

The power conversion device 200 is connected between the power source 100 and the load 300. The power conversion device 200 according to the embodiment 3 is a three-phase inverter. The power conversion device 200 converts direct current power supplied from the power source 100 into alternating current power. The power conversion device 200 supplies the alternating current power to the load 300.

The load 300 is driven by the alternating current power supplied from the power conversion device 200. The load 300 according to the embodiment 3 is a three-phase electrical motor. Usages of the three-phase electrical motor are not limited to a specific usage. The three-phase electrical motor is mounted to various electrical apparatuses. The three-phase electrical motor is mounted to a hybrid car, an electrical car, a rail vehicle, an elevator, or an air-conditioning equipment, for example.

The power conversion device 200 is described in detail hereinafter. The power conversion device 200 includes a main conversion circuit 201, a drive circuit 201, and a control circuit 203.

The main conversion circuit 201 includes a three-phase full-bridge circuit (not shown) having two levels. The three-phase full-bridge circuit includes six switching elements (not shown) and six reflux diodes (not shown).

At least one element of the switching element and the reflux diode corresponds to the semiconductor element described in the embodiment 1 or 2. In other words, the main conversion circuit 201 includes the semiconductor device 101 described in the embodiment 1 or the semiconductor device 102 described in the embodiment 2.

The three-phase full-bridge circuit includes three upper arms and three lower arms. Each of the upper arms and the lower arms includes one switching element and one reflux diode antiparallelly connected to the one switching element. The switching element included in one upper arm is connected in series to the switching element included in one lower arm to constitute one set of upper-lower arms. Three groups of upper-lower arms correspond to a U phase, a V phase, and a W phase of three-phase full-bridge circuit, respectively. An output terminal of each of three groups of upper-lower arms, that is to say, three output terminals of the main conversion circuit 201 are connected to the load 300.

The main conversion circuit 201 convers the direct current power supplied from the power source 100 into the alternating current power when the switching element performs a switching operation. The main conversion circuit 201 supplies the alternating current power to the load 300 via the output terminal.

The drive circuit 202 generates a drive signal for driving the switching element of the main conversion circuit 201 in accordance with a control signal outputted from the control circuit 203. The drive circuit 202 supplies the drive signal to a control electrode of the switching element of the main conversion circuit 201.

The drive signal is a signal for making the switching element enter an on state or an off state. More specifically, the drive signal in a case where the switching element is kept in the on state is a voltage signal (on signal) of voltage equal to or larger than threshold voltage of the switching element. The drive signal in a case where the switching element is kept in the off state is a voltage signal (off signal) of voltage smaller than threshold voltage of the switching element.

The control circuit 203 outputs a control signal for controlling the drive circuit 202 to the drive circuit 202. At that time, the control circuit 203 calculates a time at which each switching element of the main conversion circuit 201 needs to enter the on state (on time) based on the electrical power which needs to be supplied to the load 300 to generate the control signal. That is to say, the control circuit 203 generates the control signal so that pulse width modulation (PWM) control is performed on the main conversion circuit 201. The control circuit 203 outputs the control signal to the drive circuit 202 so that the drive circuit 202 outputs the on signal to the switching element which needs to enter the on state and outputs the off signal to the switching element which needs to enter the off state. In this manner, the control circuit 203 controls the switching element of the main conversion circuit 201 to supply desired electrical power to the load 300.

The semiconductor device 101 described in the embodiment 1 or the semiconductor device 102 described in the embodiment 2 is applied to the main conversion circuit 201 according to the embodiment 3, thus reliability of the power conversion device 200 is improved.

Described in the embodiment 3 is the example that the power conversion device 200 is the three-phase inverter having two levels, however, the configuration of the power conversion device 200 is not limited thereto. For example, the power conversion device 200 may be a power conversion device having multiple levels such as three levels. The power conversion device 200 may be a single-phase inverter for supplying electrical power to a single-phase load. When the load 300 is a direct current load, the power conversion device 200 may be a DC/DC converter or an AC/DC converter. When the load 300 is a solar power generation system or an electrical storage system, for example, the power conversion device 200 may be a power conditioner.

Described in the embodiment 3 is the example that the load 300 is the three-phase electrical motor, however, the configuration of the load 300 is not limited thereto. For example, the load 300 may be an electrical discharge machine, a laser beam machine, an induction heat cooking machine, or a non-contact chagrining system.

In the present disclosure, each embodiment can be arbitrarily combined, or each embodiment can be appropriately varied or omitted.

The aspects of the present disclosure are collectively described hereinafter as appendixes.

### Appendix 1

A semiconductor device, comprising:
a semiconductor substrate;
a front surface electrode containing Al and provided to a front surface of the semiconductor substrate;
a first metal layer containing Ni and provided on the front surface electrode; and
a second metal layer containing Ni and provided on the first metal layer, wherein
a surface roughness of the first metal layer is larger than a surface roughness of the second metal layer.

### Appendix 2

The semiconductor device according to Appendix 1, further comprising
a front surface-side noble metal film containing nobler metal than the second metal layer and provided on the second metal layer.

### Appendix 3

The semiconductor device according to Appendix 1 or 2, further comprising:
a back surface electrode containing Al and provided to a back surface of the semiconductor substrate;
a third metal layer containing Ni and provided on the back surface electrode; and
a fourth metal layer containing Ni and provided on the third metal layer, wherein
a surface roughness of the third metal layer is larger than a surface roughness of the fourth metal layer.

### Appendix 4

The semiconductor device according to Appendix 3, further comprising
a back surface-side noble metal film containing nobler metal than the fourth metal layer and provided on the fourth metal layer.

### Appendix 5

The semiconductor device according to Appendix 3 or 4, wherein
a composition of the third metal layer is a same as a composition of the first metal layer, and
a composition of the fourth metal layer is a same as a composition of the second metal layer.

### Appendix 6

A power conversion device, comprising:
a main conversion circuit including the semiconductor device according to any one of Appendixes 1 to 5, converting electrical power inputted from a power source, and outputting the electrical power to a load;
a drive circuit outputting a drive signal for driving the semiconductor device to the semiconductor device; and
a control circuit outputting a control signal for controlling the drive circuit to the drive circuit.

### Appendix 7

A method of manufacturing a semiconductor device, comprising:
a step of forming a front surface electrode containing Al on a front surface of a semiconductor substrate;
a step of forming a first metal layer containing Ni on the front surface electrode; and
a step of forming a second metal layer containing Ni on the first metal layer, wherein
a surface roughness of the first metal layer is larger than a surface roughness of the second metal layer.

### Appendix 8

The method of manufacturing the semiconductor device according to Appendix 7, wherein
the first metal layer and the second metal layer are formed by a non-electrolytic plating method, and
an agitation speed of a plating solution in the step of forming the first metal layer is larger than an agitation speed of the plating solution in the step of forming the second metal layer.

### Appendix 9

The method of manufacturing the semiconductor device according to Appendix 7 or 8, further comprising
a step of forming a front surface-side noble metal film containing nobler metal than the second metal layer on the second metal layer.

### Appendix 10

The method of manufacturing the semiconductor device according to any one of Appendixes 7 to 9, comprising:
a step of forming a back surface electrode containing Al on a back surface of the semiconductor substrate;
a step of forming a third metal layer containing Ni on the back surface electrode; and
a step of forming a fourth metal layer containing Ni on the third metal layer, wherein
a surface roughness of the third metal layer is larger than a surface roughness of the fourth metal layer.

### Appendix 11

The method of manufacturing the semiconductor device according to Appendix 10, wherein
the third metal layer and the fourth metal layer are formed by a non-electrolytic plating method, and
an agitation speed of a plating solution in the step of forming the third metal layer is larger than an agitation speed of the plating solution in the step of forming the fourth metal layer.

### Appendix 12

The method of manufacturing the semiconductor device according to Appendix 10 or 11, further comprising
a step of forming a back surface-side noble metal film containing nobler metal than the fourth metal layer on the fourth metal layer.

### Appendix 13

The method of manufacturing the semiconductor device according to any one of Appendixes 10 to 12, wherein
the first metal layer, the second metal layer, the third metal layer, and the fourth metal layer are formed by a non-electrolytic plating method,
the step of forming the third metal layer is performed together with the step of forming the first metal layer,
the step of forming the fourth metal layer is performed together with the step of forming the second metal layer, and
an agitation speed of a plating solution in the step of forming the first metal layer and the step of forming the third metal layer is larger than an agitation speed of the plating solution in the step of forming the second metal layer and the step of forming the fourth metal layer.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
a semiconductor substrate;
a front surface electrode containing Al and provided to a front surface of the semiconductor substrate;
a first metal layer containing Ni and provided on the front surface electrode; and
a second metal layer containing Ni and provided on the first metal layer, wherein
a surface roughness of the first metal layer is larger than a surface roughness of the second metal layer.

2. The semiconductor device according to claim 1, further comprising
a front surface-side noble metal film containing nobler metal than the second metal layer and provided on the second metal layer.

3. The semiconductor device according to claim 1, further comprising:
a back surface electrode containing Al and provided to a back surface of the semiconductor substrate;
a third metal layer containing Ni and provided on the back surface electrode; and
a fourth metal layer containing Ni and provided on the third metal layer, wherein
a surface roughness of the third metal layer is larger than a surface roughness of the fourth metal layer.

4. The semiconductor device according to claim 3, further comprising
a back surface-side noble metal film containing nobler metal than the fourth metal layer and provided on the fourth metal layer.

5. The semiconductor device according to claim 3, wherein
a composition of the third metal layer is a same as a composition of the first metal layer, and
a composition of the fourth metal layer is a same as a composition of the second metal layer.

6. A power conversion device, comprising:
a main conversion circuit including the semiconductor device according to claim 1, converting electrical power inputted from a power source, and outputting the electrical power to a load;
a drive circuit outputting a drive signal for driving the semiconductor device to the semiconductor device; and
a control circuit outputting a control signal for controlling the drive circuit to the drive circuit.

7. A method of manufacturing a semiconductor device, comprising:
a step of forming a front surface electrode containing Al on a front surface of a semiconductor substrate;
a step of forming a first metal layer containing Ni on the front surface electrode; and
a step of forming a second metal layer containing Ni on the first metal layer, wherein
a surface roughness of the first metal layer is larger than a surface roughness of the second metal layer.

8. The method of manufacturing the semiconductor device according to claim 7, wherein
the first metal layer and the second metal layer are formed by a non-electrolytic plating method, and
an agitation speed of a plating solution in the step of forming the first metal layer is larger than an agitation speed of the plating solution in the step of forming the second metal layer.

9. The method of manufacturing the semiconductor device according to claim 7, further comprising
a step of forming a front surface-side noble metal film containing nobler metal than the second metal layer on the second metal layer.

10. The method of manufacturing the semiconductor device according to claim 7, comprising:
a step of forming a back surface electrode containing Al on a back surface of the semiconductor substrate;
a step of forming a third metal layer containing Ni on the back surface electrode; and
a step of forming a fourth metal layer containing Ni on the third metal layer, wherein
a surface roughness of the third metal layer is larger than a surface roughness of the fourth metal layer.

11. The method of manufacturing the semiconductor device according to claim 10, wherein
the third metal layer and the fourth metal layer are formed by a non-electrolytic plating method, and
an agitation speed of a plating solution in the step of forming the third metal layer is larger than an agitation speed of the plating solution in the step of forming the fourth metal layer.

12. The method of manufacturing the semiconductor device according to claim 10, further comprising
a step of forming a back surface-side noble metal film containing nobler metal than the fourth metal layer on the fourth metal layer.

13. The method of manufacturing the semiconductor device according to claim 10, wherein
the first metal layer, the second metal layer, the third metal layer, and the fourth metal layer are formed by a non-electrolytic plating method,
the step of forming the third metal layer is performed together with the step of forming the first metal layer,
the step of forming the fourth metal layer is performed together with the step of forming the second metal layer, and
an agitation speed of a plating solution in the step of forming the first metal layer and the step of forming the third metal layer is larger than an agitation speed of the plating solution in the step of forming the second metal layer and the step of forming the fourth metal layer.
